(19) United States
(12) Patent Application Publication
(10) Pub. No.: US 2026/0150709 A1
(43) Pub. Date: May 28, 2026

(54) SEMICONDUCTOR PACKAGE HAVING VERTICALLY STACKED TRANSISTORS AND METHOD OF MAKING THE SAME

(71) Applicant: ALPHA AND OMEGA SEMICONDUCTOR INTERNATIONAL LP, TORONTO (CA)

(72) Inventors: Yan Xun Xue, Los Gatos, CA (US); Sik Lui, Sunnyvale, CA (US); Madhur Bobde, Sunnyvale, CA (US); Long-Ching Wang, Cupertino, CA (US); Zhiqiang Niu, Santa Clara, CA (US); Chunya Wen, Santa Clara, CA (US); Kuan-Hung Li, Zhubei City (TW); Lin Lv, Shanghai (CN)

(73) Assignee: ALPHA AND OMEGA SEMICONDUCTOR INTERNATIONAL LP, TORONTO, ON (CA)

(21) Appl. No.: 18/958,514

(22) Filed: Nov. 25, 2024

(51) Int. Cl. H01L 23/00; H01L 23/31; H01L 23/495

(52) U.S. Cl. CPC H10W 70/421; H10W 72/076; H10W 72/07652; H10W 72/07653; H10W 72/627; H10W 74/111; H10W 90/766

(57) ABSTRACT

A semiconductor package comprising a lead frame, a vertically stacked field-effect transistor (FET) set, a source clip, a gate clip, and a molding encapsulation. The vertically stacked FET set comprises a first FET, and a second FET. The first FET is flipped. A method comprising the steps of providing a lead frame; attaching a vertically stacked FET set, attaching clip(s), forming a molding encapsulation; and applying a singulation process.

### FIELD OF THE INVENTION

This invention relates generally to a semiconductor package and a method of making the same. More particularly, the present invention relates to a double-diffusion metal-oxide-silicon field-effect transistor (DMOS FET) having vertically stacked transistors.

### BACKGROUND OF THE INVENTION

A power control module (PCM) uses DMOS FETs. A DMOS FET includes electrodes on both top side and bottom side. One requirement is to maintain low resistance. A conventional PCM includes a pair of side-by-side DMOS FETs. To reduce the resistance, a thick metal (larger than 30 microns thick) is attached to the pair of side-by-side DMOS FETs thereby increasing a size of the PCM.

A semiconductor package of the present disclosure includes a pair of vertically stacked FETs thereby facilitating reduced resistance (20% reduction). A horizontal dimension is reduced by 35% (from 2 mm by 3.6 mm to 1.3 mm by 3.6 mm). The production rate, number of products per hour (NPH) is also increased.

### SUMMARY OF THE INVENTION

The present invention discloses a semiconductor package comprising a lead frame, a vertically stacked FET set, a source clip, a gate clip, and a molding encapsulation. The vertically stacked FET set comprises a first FET, and a second FET. The first FET is flipped.

A method for fabricating a semiconductor package is also disclosed. The method comprises the steps of providing a lead frame; attaching a vertically stacked FET set, attaching clip(s), forming a molding encapsulation; and applying a singulation process.

### BRIEF DESCRIPTION OF THE DRAWINGS

FIG. 1A is a top perspective view, FIG. 1B is a bottom perspective view, and FIG. 1C is an exploded plot of a semiconductor package in examples of the present disclosure.

FIG. 2 is side view of a vertically stacked FET set in examples of the present disclosure.

FIG. 3 is a flowchart of a process to fabricate a semiconductor package in examples of the present disclosure.

FIGS. 4A, 4B, 4C, 4D, and 4E show the steps of the process to fabricate the semiconductor package in examples of the present disclosure.

FIG. 5A is a top view of a lead frame strip and FIG. 5B is a top view of a clip strip in examples of the present disclosure.

FIG. 6 is a flowchart of a process to fabricate a vertically stacked FET set in examples of the present disclosure.

FIGS. 7A, 7B, 7C and 7D show the steps of the process to fabricate the vertically stacked FET set in examples of the present disclosure.

### DETAILED DESCRIPTION OF THE INVENTION

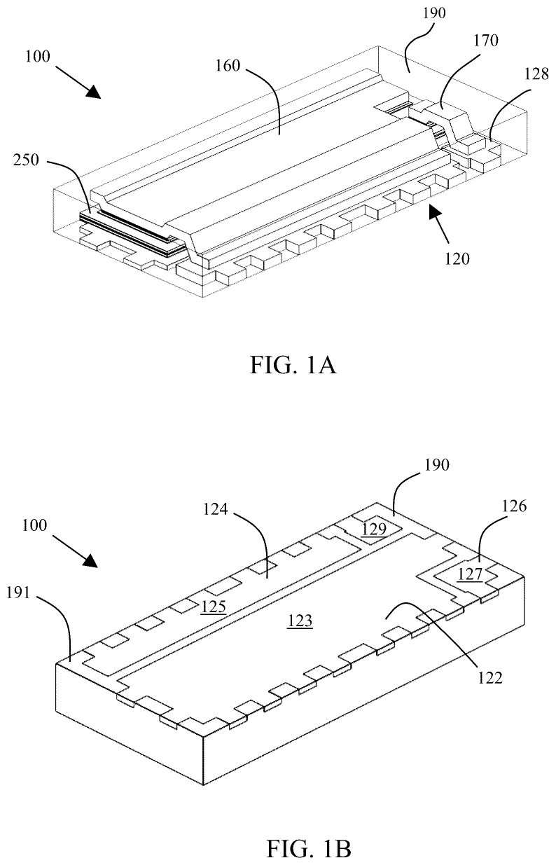

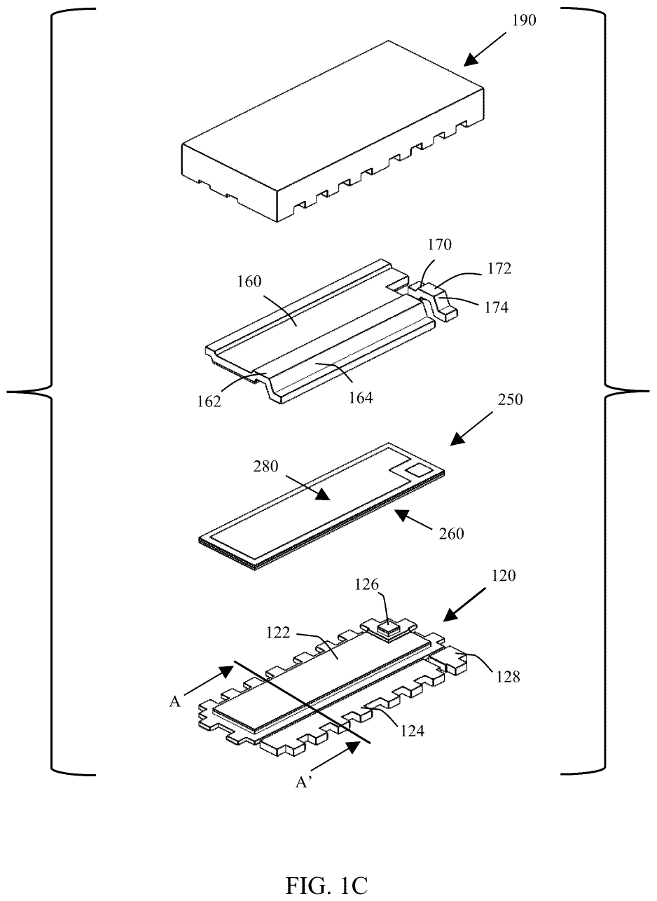

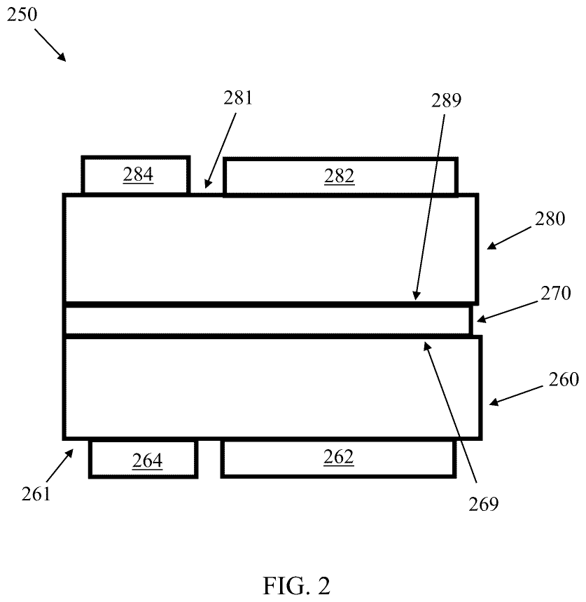

FIG. 1A is a top perspective view, FIG. 1B is a bottom perspective view, and FIG. 1C is an exploded plot of a semiconductor package 100 in examples of the present disclosure. FIG. 2 is side view of a vertically stacked FET set 250 in examples of the present disclosure. In one example, the semiconductor package 100 is a DMOS FET. The semiconductor package 100 comprises a lead frame 120, the vertically stacked FET set 250, a source clip 160, a gate clip 170, and a molding encapsulation 190. The lead frame 120 comprises a die paddle 122, a side paddle 124, a first gate paddle 126, and a second gate paddle 128.

The vertically stacked FET set 250 comprises a first FET 260 and a second FET 280 in a back to back connection. The first FET 260 comprises a source electrode 262 and a gate electrode 264 on a front surface 261 of the first FET 260. The second FET 280 comprises a source electrode 282 and a gate electrode 284 on a front surface 281 of the second FET 280 opposite the front surface 261 of the first FET 260. A drain electrode 269 of the first FET 260 and a drain electrode 289 of the second FET 280 are connected internally. The first FET 260 is flipped with its source electrode 262 attached to the die paddle 122 and its gate electrode 264 attached to the first gate paddle 126.

The source clip 160 electrically and mechanically connects the source electrode 282 of the second FET 280 to the side paddle 124 of the lead frame 120. The gate clip 170 electrically and mechanically connects the gate electrode 284 of the second FET 280 to the second gate paddle 128 of the lead frame 120.

The molding encapsulation 190 encloses the first FET 260, the second FET 280, the source clip 160, the gate clip 170, a majority portion of the first gate paddle 126, a majority portion of the second gate paddle 128, and a majority portion of the lead frame 120 (a majority portion of the die paddle 122, a majority of the side paddle 124, a majority portion of the first gate paddle 126, and a majority portion of the second gate paddle 128). A majority portion refers to larger than 50%.

A bottom surface 123 of the die paddle 122, a bottom surface 125 of the side paddle 124, a bottom surface 127 of the first gate paddle 126, and a bottom surface 129 of the second gate paddle 128 are exposed from a bottom surface 191 of the molding encapsulation 190.

In examples of the present disclosure, the source clip 160 is made of metal. In one example, the source clip 160 is made of cupper. In examples of the present disclosure, the gate clip 170 is made of metal. In one example, the gate clip 170 is made of cupper.

The source clip 160 comprises a raised portion 162 and a slanting portion 164. The gate clip 170 comprises a raised portion 172 and a slanting portion 174. In examples of the present disclosure, a top surface of the raised portion 162 of the source clip 160 and a top surface of the raised portion 172 of the gate clip 170 are co-planar.

In examples of the present disclosure, the first FET 260 and the second FET 280 are formed on different substrates and the vertically stacked FET set 250 comprises the first FET 260 and the second FET 280 back to back bonding together. An optional conductive bonding layer 270 bonds the drain electrode 269 on the back surface of the first FET 260 to the drain electrode 289 on the back surface of the second FET 280 to form the vertically stacked FET set 250 as common drain MOSFETs. In one example of the present disclosure, the bonding layer 270 comprises gold and serves as a common drain region connecting the drain electrode 269 of the first FET 260 to the drain electrode 289 of the second FET 280.

In examples of the present disclosure, the first FET 260, and the second FET 280 are formed from a same semiconductor substrate (see U.S. Pat. No. 10,446,545 to Lui et al. and US Patent Application No.: 2018/0006026 to Lui et al.). In examples of the present disclosure, the first FET 260, and the second FET 280 are single piece construction.

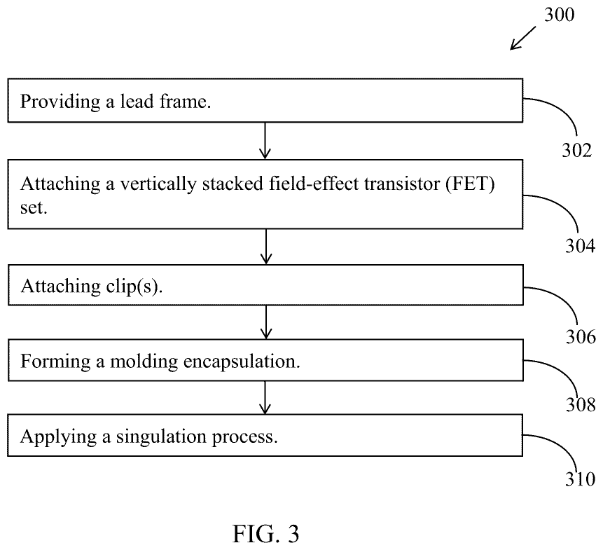

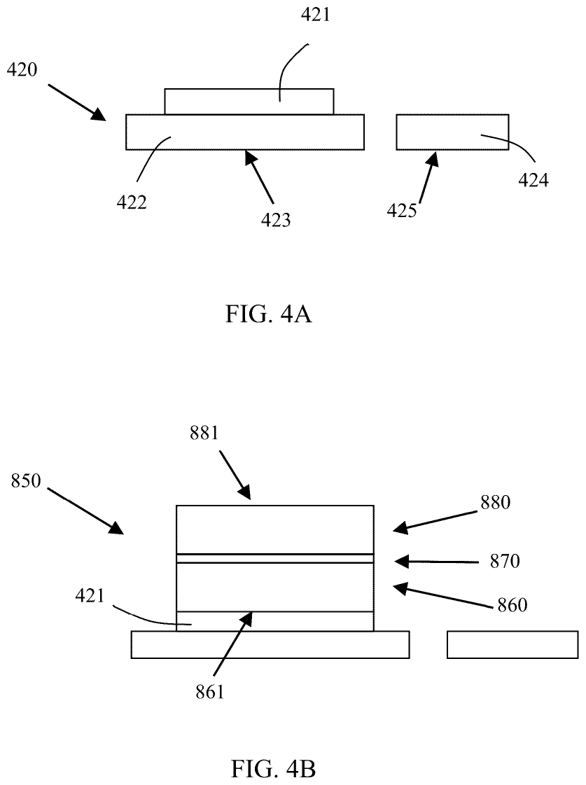

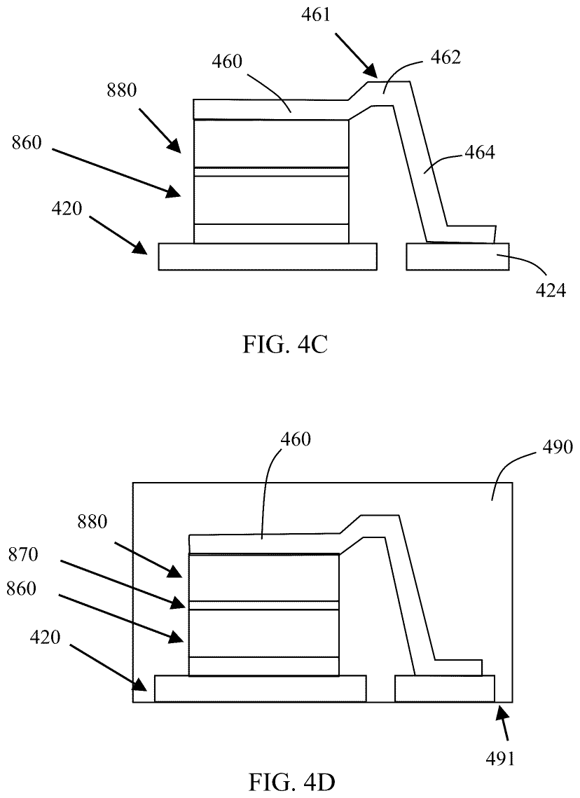

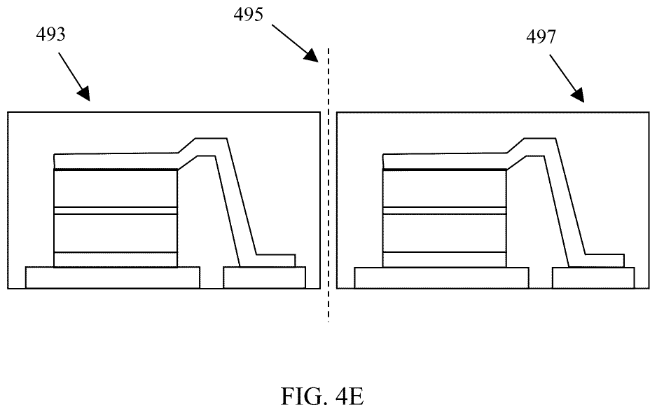

FIG. 3 is a flowchart of a process 300 to fabricate a semiconductor package in examples of the present disclosure. The process 300 may start from block 302. For simplicity, only the process to fabricate a single package is shown in FIGS. 4A, 4B, 4C, and 4D. For simplicity, only the process to fabricate two semiconductor packages is shown in FIG. 4E. FIGS. 4A, 4B, 4C, 4D, and 4E are cross-sectional views along AA′ of FIG. 1C.

In block 302, referring now to FIG. 4A, a lead frame 420 is provided. The lead frame 420 comprises a die paddle 422, a side paddle 424, a first gate paddle 126 of FIG. 1B, and a second gate paddle 128 of FIG. 1A. In examples of the present disclosure, solder paste 421 is dispensed on the die paddle 422 of the lead frame 420. Block 302 may be followed by block 304.

In block 304, referring now to FIG. 4B, a vertically stacked FET set 850 is attached. In examples of the present example, the vertically stacked FET set 850 is attached to the solder paste 421. The vertically stacked FET set 850 comprises a first FET 860, and a second FET 880. The first FET 860 is flipped and attached to the die paddle 422 through the solder paste 421. The first FET 860 comprises a source electrode 262 of FIG. 2 and a gate electrode 264 of FIG. 2 on a front surface 861 of the first FET 860. The second FET 880 is attached back to back to the first FET 860. The second FET 880 comprises a source electrode 282 of FIG. 2 and a gate electrode 284 of FIG. 2 on a front surface 881 of the second FET 880.

In examples of the present disclosure, the first FET 860 and the second FET 880 are formed on different substrates and the vertically stacked FET set 850 comprises the first FET 860 and the second FET 880 back to back bonding together. An optional conductive bonding layer 870 bonds the drain electrode on the back surface of the first FET 860 to the drain electrode on the back surface of the second FET 880 to form the vertically stacked FET set 850 as common drain MOSFETs. The optional conductive bonding layer 870 is served as a common drain region connects a drain electrode 269 of FIG. 2 of the first FET 860 to a drain electrode 289 of FIG. 2 of the second FET 880.

In examples of the present disclosure, the first FET 860 and the second FET 880 are formed from a same semiconductor substrate (see U.S. Pat. No. 10,446,545 to Lui et al. and US Patent Application No.: 2018/0006026 to Lui et al.). In examples of the present disclosure, the first FET 860, and the second FET 880 are single piece construction. Block 304 may be followed by block 306.

In block 306, referring now to FIG. 4C, clip(s) are attached. The source clip 460 electrically and mechanically connects the source electrode 282 of FIG. 2 of the second FET 880 to the side paddle 424 of the lead frame 420. The gate clip 170 of FIG. 1A electrically and mechanically connects the gate electrode 284 of FIG. 2 of the second FET 880 to the second gate paddle 128 of FIG. 1A of the lead frame 420. The gate electrode 264 of FIG. 2 of the first FET 860 is attached to the first gate paddle 126 of FIG. 1B of the lead frame 420.

In examples of the present disclosure, the source clip 460 is made of metal. In one example, the source clip 460 is made of cupper. In examples of the present disclosure, the gate clip 170 of FIG. 1A is made of metal. In one example, the gate clip 170 of FIG. 1A is made of cupper.

The source clip 460 comprises a raised portion 462 and a slanting portion 464. The gate clip 170 of FIG. 1C comprises a raised portion 172 of FIG. 1C and a slanting portion 174 of FIG. 1C. In examples of the present disclosure, a top surface 461 of the raised portion 162 of the source clip 160 and a top surface of the raised portion 172 of FIG. 1C of the gate clip 170 of FIG. 1C are co-planar. Block 306 may be followed by block 308.

In block 308, referring now to FIG. 4D, a molding encapsulation 490 is formed. The molding encapsulation 490 encloses the first FET 860, the second FET 880, the source clip 460, the gate clip 170 of FIG. 1A, and a majority portion of the lead frame 420 (a majority portion of the die paddle 422, a majority of the side paddle 424, a majority portion of the first gate paddle 126 of FIG. 1B, and a majority portion of the second gate paddle 128 of FIG. 1A). A majority portion refers to larger than 50%.

A bottom surface 423 of the die paddle 422, a bottom surface 425 of the side paddle 424, a bottom surface 127 of FIG. 1B of the first gate paddle 126 of FIG. 1B, and a bottom surface 129 of FIG. 1B of the second gate paddle 128 of FIG. 1A are exposed from a bottom surface 491 of the molding encapsulation 490. Block 308 may be followed by block 310.

In block 310, referring now to FIG. 4E, a singulation process along the line 495 is applied. The semiconductor package 493 is separated from an adjacent semiconductor package 497. Although only two semiconductor packages are shown in FIG. 4E, the number of semiconductor packages to be separated in a same singulated process may vary. In examples of the present disclosure, the semiconductor package 493 is a DMOS FET.

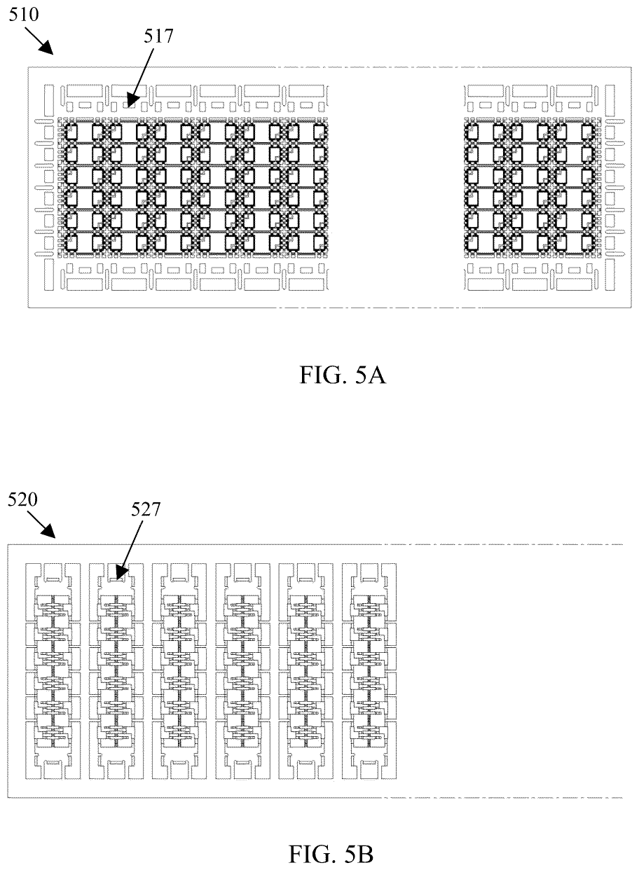

In examples of the present disclosure, block 302 comprises the sub-steps of providing a lead frame strip 510 of FIG. 5A. The lead frame strip 510 comprises a plurality of locking holes 517. In examples of the present disclosure, each of the plurality of locking holes 517 of the lead frame strip 510 is of a first rectangular shape. Block 306 comprises the sub-steps of providing a clip strip 520 of FIG. 5B. The clip strip 520 comprises a plurality of locking inserts 527. In examples of the present disclosure, each of the plurality of locking inserts 527 of the clip strip 520 is of a second rectangular shape. The plurality of locking inserts 527 of the clip strip 520 are engaged to the plurality of locking holes 517 of the lead frame strip 510. In examples of the present disclosure, the plurality of locking inserts 527 of the clip strip 520 and the plurality of locking holes 517 of the lead frame strip 510 are used for both the locking and alignment purpose.

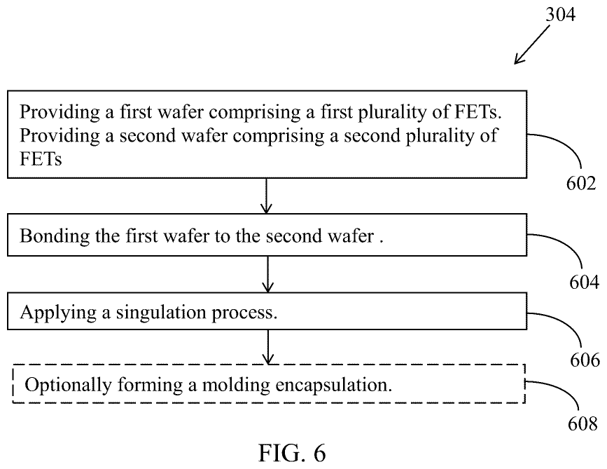

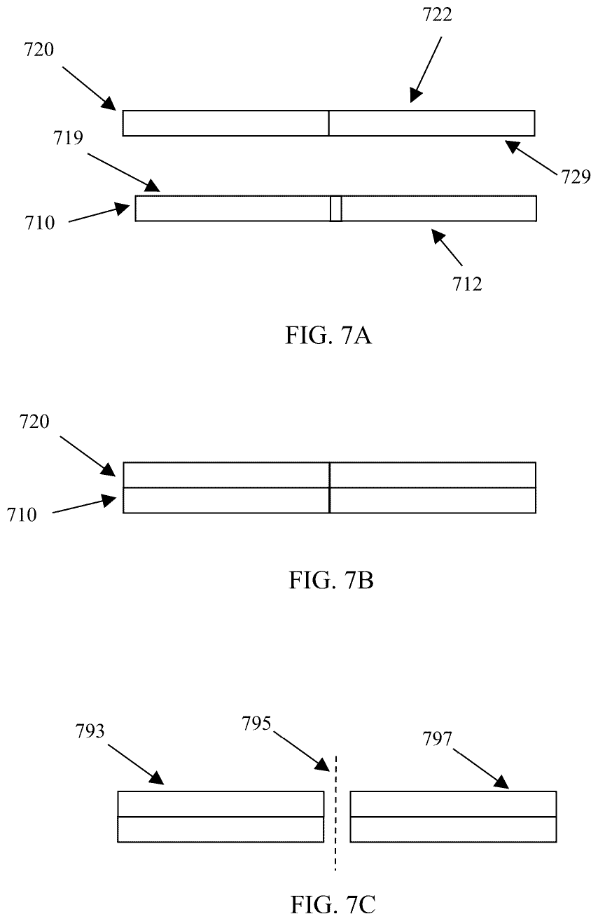

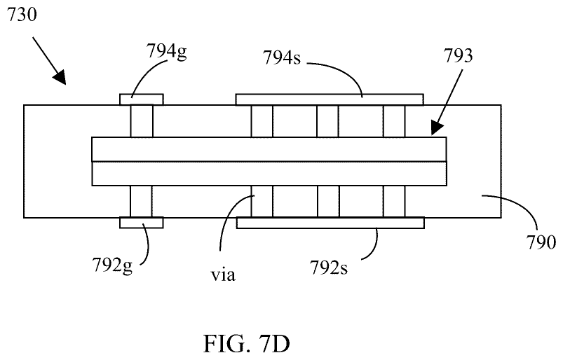

In examples of the present disclosure, block 304 comprises the sub-steps shown in FIG. 6. For simplicity, only the process to fabricate two vertically stacked FET sets are shown in FIGS. 7A, 7B, and 7C. The block 304 may start from sub-block 602.

In sub-block 602, referring now to FIG. 7A, a first wafer 710, comprising a first plurality of FETs including a first FET 712, is provided. A second wafer 720, comprising a second plurality of FETs including a second FET 722, is also provided. In examples of the present example, the first wafer 710 is flipped. Sub-block 602 may be followed by sub-block 604.

In sub-block 604, referring now to FIG. 7B, a bottom surface 719 of FIG. 7A of the first wafer 710 is bonded to a bottom surface 729 of FIG. 7A of the second wafer 720 by an eutectic wafer bonding process, a transient liquid phase wafer bonding process, or a metal thermal-compression wafer bonding process. Although not shown here, an optional conductive bonding layer such as layer 270 or layer 870 may be used to facilitate the wafer bonding process. Sub-block 604 may be followed by sub-block 606.

In sub-block 606, referring now to FIG. 7C, a singulation process along the line 795 is applied. The vertically stacked FET set 793 is separated from an adjacent vertically stacked FET set 797. Although only two vertically stacked FET sets are shown in FIG. 7C, the number of vertically stacked FET sets to be separated in a same singulated process may vary. Sub-block 606 may be followed by optional sub-block 608 to form an embedded package 730.

In optional sub-block 608 (shown in dashed lines), referring now to FIG. 7D, a molding encapsulation 790 is formed. The molding encapsulation 790 completely encloses the vertically stacked FET set 793 on all surfaces. Connection vias are formed from a bottom surface of the molding encapsulation 790 to reach the first FET and from a front surface of the molding encapsulation 790 to reach the second FET. A metallization process such as plating is applied to form metal connections. As shown in FIG. 7D, the embedded package 730 comprises a first gate metal section 792g and a first source metal section 792s disposed on the bottom surface of the molding encapsulation 790. The first gate metal section 792g is connected to a gate electrode of the first FET through a first gate connection via. The first source metal section 792s is connected to a source electrode of the first FET through a first plurality of source connection vias. A second gate metal section 794g and a second source metal section 794s are disposed on a front surface of the molding encapsulation 790. The second gate metal section 794g is connected to a gate electrode of the second FET through a second gate connection via. The second source metal section 794s is connected to a source electrode of the second FET through a second plurality of source connection vias. Each of the first gate metal section 792g, the first source metal section 792s, the second gate metal section 794g and the second source metal section 794s preferably comprises a solderable metal, such as copper, gold or silver.

In examples of the present disclosure, the embedded package 730 comprises the vertically stacked FET set 793 comprising the first FET 712 and the second FET 722 formed on different substrates and the first FET 712 and the second FET 722 are back to back bonding together. An optional conductive bonding layer such as layer 270 or layer 870 bonds the drain electrode on the back surface of the first FET 712 to the drain electrode on the back surface of the second FET 722 to form the vertically stacked FET set 793 as common drain MOSFETs. In one example of the present disclosure, the bonding layer comprises gold and serves as a common drain region connecting the drain electrode of the first FET 712 to the drain electrode of the second FET 722.

In examples of the present disclosure, the embedded package 730 comprises the vertically stacked FET set 793 comprising the first FET 712 and the second FET 722 formed on a same semiconductor substrate (see U.S. Pat. No. 10,446,545 to Lui et al. and US Patent Application No.: 2018/0006026 to Lui et al.). In examples of the present disclosure, the first FET 712, and the second FET 722 are single piece construction.

Those of ordinary skill in the art may recognize that modifications of the embodiments disclosed herein are possible. For example, a height of the slanting portion 164 and a height of the slanting portion 464 may vary. Other modifications may occur to those of ordinary skill in this art, and all such modifications are deemed to fall within the purview of the present invention, as defined by the claims.

1. A semiconductor package comprising:
a lead frame comprising
a die paddle; and
a side paddle;
a vertically stacked FET comprising
a first field-effect transistor (FET) and a second FET in a back to back connection, the first FET comprising a source electrode and a gate electrode on a front surface of the first FET, the first FET being flipped and attached to the die paddle;
the second FET comprising a source electrode and a gate electrode on a front surface of the second FET opposite the front surface of the first FET;
a source clip connecting the source electrode of the second FET to the side paddle of the lead frame; and
a molding encapsulation enclosing the first FET, the second FET, the source clip, and a majority portion of the lead frame.

2. The semiconductor package of claim 1 further comprising:
a gate clip;
wherein the lead frame further comprises:
a first gate paddle; and
a second gate paddle;
wherein the gate electrode of the first FET is attached to the first gate paddle of the lead frame;
wherein the gate clip connects the gate electrode of the second FET to the second gate paddle of the lead frame; and
wherein the molding encapsulation further encloses the gate clip, a majority portion of the first gate paddle, and a majority portion of the second gate paddle.

3. The semiconductor package of claim 2, wherein the gate clip is made of metal; and
wherein the gate clip comprises:
a raised portion; and
a slanting portion.

4. The semiconductor package of claim 2, wherein a bottom surface of the die paddle, a bottom surface of the side paddle, a bottom surface of the first gate paddle, and a bottom surface of the second gate paddle are exposed from a bottom surface of the molding encapsulation.

5. The semiconductor package of claim 1, wherein the source clip is made of metal; and
wherein the source clip comprises:
a raised portion; and
a slanting portion.

6. The semiconductor package of claim 1, further comprises a bonding layer serving as a common drain region connecting a drain electrode of the first FET to a drain electrode of the second FET.

7. The semiconductor package of claim 1, wherein the first FET and the second FET are formed from a same semiconductor substrate.

8. The semiconductor package of claim 1, wherein the semiconductor package is a double-diffusion metal-oxide-silicon field-effect transistor (DMOS FET).

9. A method for fabricating a semiconductor package, the method comprising the steps of:
providing a lead frame comprising
a die paddle; and
a side paddle;
attaching a vertically stacked field-effect transistor (FET) set comprising:
a first field-effect transistor (FET) being flipped and attached to the die paddle, the first FET comprising a source electrode and a gate electrode on a front surface of the first FET;
a second FET back to back attached to the first FET, the second FET comprising a source electrode and a gate electrode on a front surface of the second FET;
attaching a source clip connecting the source electrode of the second FET to the side paddle of the lead frame;
forming a molding encapsulation enclosing the first FET, the second FET, the source clip, and a majority portion of the lead frame; and
applying a singulation process separating the semiconductor package from adjacent semiconductor packages.

10. The method of claim 9 further comprising the step of
attaching a gate clip;
wherein the lead frame further comprises:
a first gate paddle; and
a second gate paddle;
wherein the gate electrode of the first FET is attached to the first gate paddle of the lead frame;
wherein the gate clip connects the gate electrode of the second FET to the second gate paddle of the lead frame; and
wherein the molding encapsulation further encloses the gate clip, a majority portion of the first gate paddle, and a majority portion of the second gate paddle.

11. The method of claim 10, wherein a bottom surface of the die paddle, a bottom surface of the side paddle, a bottom surface of the first gate paddle, and a bottom surface of the second gate paddle are exposed from a bottom surface of the molding encapsulation.

12. The method of claim 9, wherein a common drain region connects a drain electrode of the first FET to a drain electrode of the second FET.

13. The method of claim 9, wherein the first FET, and the second FET are formed from a same semiconductor substrate.

14. The method of claim 9, wherein the step of attaching the vertically stacked FET set comprising the sub-steps of
providing a first wafer comprising a first plurality of FETs;
providing a second wafer comprising a second plurality of FETs;
bonding a bottom surface of the first wafer to a bottom surface of the second wafer by an eutectic wafer bonding process, a transient liquid phase wafer bonding process, or a metal thermal-compression wafer bonding process; and
applying another singulation process forming a plurality of vertically stacked FET sets comprising the vertically stacked FET set.

15. The method of claim 9, wherein the step of providing the lead frame comprising the sub-steps of:
providing a lead frame strip comprising:
a plurality of locking holes; and
wherein the step of attaching the source clip comprising the sub-steps of:
providing a clip strip comprising:
a plurality of locking inserts; and
engaging the plurality of locking inserts of the clip strip to the plurality of locking holes of the lead frame strip.

16. The method of claim 15, wherein each of the plurality of locking holes of the lead frame strip is of a first rectangular shape; and
Each of the plurality of locking inserts of the clip strip is of a second rectangular shape.

17. A semiconductor package comprising:
a vertically stacked FET comprising:
a first field-effect transistor (FET) and a second FET in a back to back connection,
the first FET comprising a source electrode and a gate electrode on a front surface of the first FET, and
the second FET comprising a source electrode and a gate electrode on a front surface of the second FET opposite the front surface of the first FET;
a molding encapsulation enclosing the first FET and the second FET, the molding encapsulation comprising:
a bottom surface overlaying the front surface of the first FET; and
a front surface overlaying the front surface of the second FET;
a first gate metal section disposed on the bottom surface of the molding encapsulation, the first gate metal section being connected to the gate electrode of the first FET through a first gate connection via;
a first source metal section disposed on the bottom surface of the molding encapsulation, the first source metal section being connected to the source electrode of the first FET through a first plurality of source connection vias;
a second gate metal section disposed on the front surface of the molding encapsulation, the second gate metal section being connected to the gate electrode of the second FET through a second gate connection via; and
a second source metal section disposed on the front surface of the molding encapsulation, the second source metal section being connected to the source electrode of the second FET through a second plurality of source connection vias.

18. The semiconductor package of claim 17, wherein each of the first gate metal section, the first source metal section, the second gate metal section and the second source metal section comprises a solderable metal.

19. The semiconductor package of claim 17 further comprising a bonding layer serving as a common drain region connecting a drain electrode of the first FET to a drain electrode of the second FET.

20. The semiconductor package of claim 17, wherein the first FET and the second FET are formed from a same semiconductor substrate.
